(19) United States
(12) Patent Application Publication
(10) Pub. No.: US 2024/0213132 A1
(43) Pub. Date: Jun. 27, 2024

(54) THIN FILM CAPACITORS (TFCS) IN ETCHED BACK DEEP VIA

(71) Applicant: Intel Corporation, Santa Clara, CA (US)

(72) Inventors: Kristof DARMAWIKARTA, Chandler, AZ (US); Benjamin DUONG, Phoenix, AZ (US); Darko GRUJICIC, Chandler, AZ (US); Shayan KAVIANI, Phoenix, AZ (US); Mahdi MOHAMMADIGHALENI, Phoenix, AZ (US); Suddhasattwa NAD, Chandler, AZ (US); Thomas L. SOUNART, Chandler, AZ (US); Marcel WALL, Phoenix, AZ (US); Ravindranath V. MAHAJAN, Chandler, AZ (US); Rahul N. MANEPALLI, Chandler, AZ (US)

(21) Appl. No.: 18/089,476

(22) Filed: Dec. 27, 2022

(51) Int. Cl. H01L 23/498; H01L 27/01

(52) U.S. Cl. CPC H01L 23/49838; H01L 27/016; H01L 28/86; H01L 28/90; H01L 23/49822; H01L 23/49894; H01L 24/16

(57) ABSTRACT

Embodiments disclosed herein include an electronic package. In an embodiment, the electronic package comprises a package substrate, where the package substrate comprises a plurality of stacked dielectric layers. In an embodiment, the electronic package further comprises an opening into the package substrate, where the opening passes through at least two of the plurality of dielectric layers. In an embodiment, a first pad is at the bottom of the opening, a capacitor is disposed in the opening, and a second pad is over the capacitor.

### TECHNICAL FIELD

Embodiments of the present disclosure relate to electronic packages, and more particularly to package architectures that include thin film capacitors (TFCs) that are provided in deep vias in buildup layers of a package substrate.

### BACKGROUND

Capacitors are key energy storage components for power delivery networks in semiconductor packaging applications. For example, capacitors may be used as decoupling capacitors either at the input or output of the voltage regulator to suppress switching noise. Next generation power delivery demands high voltage application, as this is presumed to improve the power routing losses at high TDP power consumption. High TDP power consumption is common in applications such as servers and graphics processors.

Current capacitor technologies, however, cannot meet the required demand. This is due, at least in part, to capacitance degradation at high frequencies, leakage or breakdown concerns at high voltages, or relatively large distances from the silicon top die that degrades efficiency. Land side or die side capacitors are typically ceramic-based capacitors that have high capacitance density. However, the drawback of such capacitors is that they generally operate at low frequencies. Additionally, land side and die side capacitors are further from the silicon die. On die metal-insulator-metal (MIM) capacitors have high capacitance density, but also suffer from high leakage at high voltages due to the ultra-thin film dielectric.

### BRIEF DESCRIPTION OF THE DRAWINGS

FIG. 1A is a cross-sectional illustration of a portion of an electronic package that illustrates a deep trench thin film capacitor (TFC), in accordance with an embodiment.

FIG. 1B is a zoomed in illustration of the TFC in FIG. 1A, in accordance with an embodiment.

FIG. 2A is a cross-sectional illustration of a portion of an electronic package that illustrates a deep trench TFC that directly contacts traces or pads along a mid-point of the TFC, in accordance with an embodiment.

FIG. 2B is a zoomed in illustration of the TFC in FIG. 2A, in accordance with an embodiment.

FIG. 3 is a cross-sectional illustration of a deep via TFC that includes a saw-tooth profile in order to increase capacitance density, in accordance with an embodiment.

FIG. 4 is a cross-sectional illustration of a deep via opening TFC that includes a cavity in the bottom pad in order to increase capacitance density, in accordance with an embodiment.

FIG. 5A is a cross-sectional illustration of a portion of a package substrate that includes fibers that pass through sidewalls of the deep via opening, in accordance with an embodiment.

FIG. 5B is a zoomed in illustration of one of the fibers with a TFC structure provided around the fiber, in accordance with an embodiment.

FIG. 6A is a cross-sectional illustration of a portion of a package substrate that includes filler particles and cavities along the sidewall of the deep via opening, in accordance with an embodiment.

FIG. 6B is a zoomed in cross-sectional illustration of a TFC that lines the cavity in the sidewall of the deep via opening, in accordance with an embodiment.

FIGS. 7A-7F are cross-sectional illustrations depicting a process for forming a deep via opening TFC in an electronic package, in accordance with an embodiment.

FIG. 8 is a cross-sectional illustration of a computing system that comprises a package substrate that includes deep via opening TFCs, in accordance with an embodiment.

FIG. 9 is a schematic of a computing device built in accordance with an embodiment.

### EMBODIMENTS OF THE PRESENT DISCLOSURE

Described herein are package architectures that include thin film capacitors (TFCs) that are provided in deep vias in buildup layers of a package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, capacitor architectures are critical components for enabling advanced packaging applications. Currently, the capacitor solutions are limited to die side and land side capacitors and on-die metal-insulator-metal (MIM) capacitors. Die side and land side capacitors are limited to low frequency operation and are spaced further from the top dies (e.g., 5 mm or more from the top dies). MIM capacitors are generally designed to operate at low voltages. Accordingly, there is a performance gap between the two types of capacitors.

Accordingly, embodiments disclosed herein include the design and fabrication of in-package capacitors that utilize deep drilled vias that span two or more buildup layers. Thin film capacitor (TFC) architectures may be used to line the deep via in order to provide high capacitance density solutions. Particularly, atomic layer deposition (ALD) or chemical vapor deposition (CVD) process can be used in order to deposit the layers of the TFCs within high aspect ratio features. In some embodiments, the TFC architectures may further include etched back regions to form a saw-tooth profile that further enhances capacitance density. In yet another embodiment, an isotropic etch of the bottom pad may also be used to increase the surface area of the TFC.

In yet another embodiment, surface area of the TFC can be increased through depositing the TFC over fibers that extend out sidewalls of the deep via. Cavities into the sidewalls of the deep via (e.g., due to the etching of filler particles) can also be used to increase the surface area of the TFC.

The TFC may be formed with a high-k dielectric material. For example, the dielectric constant of the dielectric layer may be equal to or greater than a dielectric constant of a material comprising silicon and oxygen. For example, the dielectric layer may comprise titanium and oxygen (e.g., TiO₂), hafnium and oxygen (e.g., HfO₂), polymers, and the like. The TFC may include a first electrode on one side of the dielectric layer and a second electrode on the other side of the dielectric layer. The first electrode may line the deep via opening and the second electrode may be a plug that at least partially fills a remainder of the deep via opening. In other embodiments, the second electrode may be a thin layer of conductive material, and the plug is provided over the thin layer of conductive material.

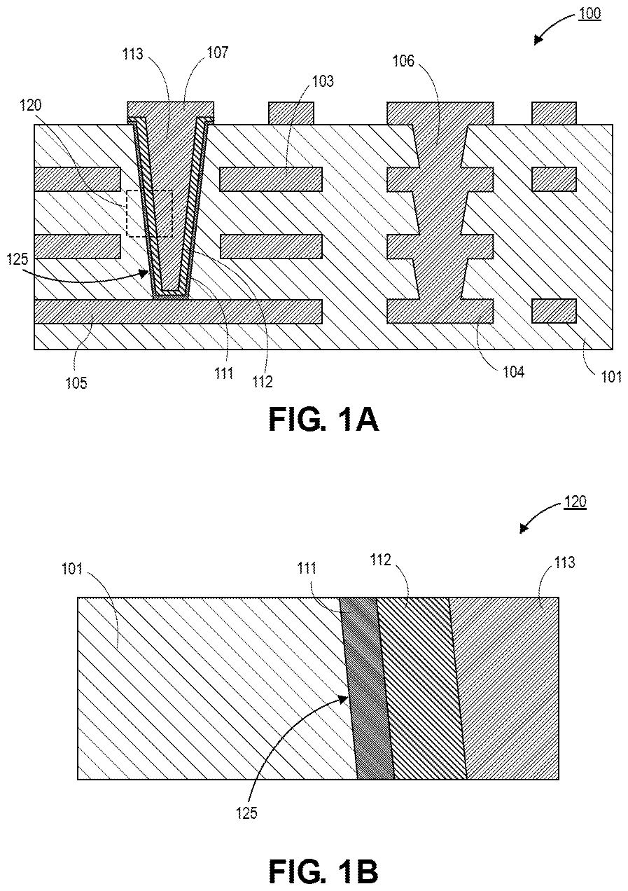

Referring now to FIG. 1A, a cross-sectional illustration of a portion of an electronic package 100 is shown, in accordance with an embodiment. In an embodiment, the electronic package 100 may include a plurality of dielectric buildup layers 101, such as buildup film. The buildup layers 101 are illustrated as a single monolithic structure, but it is to be appreciated that multiple buildup layers 101 may be laminated or otherwise provided over each other. In an embodiment, the buildup layers 101 may be provided over a core (not shown). Though, in some embodiments, the electronic package 100 may be coreless.

In an embodiment, conductive routing may be provided in the buildup layers 101. For example, pads 104, vias 106, traces 103, and the like may be provided within the buildup layers 101. The conductive routing may be fabricated with typical package assembly processes, such as semi-additive processing (SAP) or the like. In a particular embodiment, first pad 105 and second pad 107 are called out in order to reference the structure of the TFC. While shown as a trace, it is to be appreciated that first pad 105 may be a pad in some embodiments. Similarly, while second pad 107 is shown as a pad, it is to be appreciated that the second pad 107 may be a trace in some embodiments. The first pad 105 may be coupled to a ground voltage and the second pad 107 may be coupled to a power voltage or a Vcc voltage.

In an embodiment, a deep via opening 125 may extend through the buildup layers 101. For example, the deep via opening 125 may extend through two or more buildup layers 101 in some embodiments. Particularly, the deep via opening 125 may have an aspect ratio that is approximately 5:1 or greater, approximately 10:1 or greater, or approximately 20:1 or greater. The high aspect ratio is compatible with certain deposition processes that are used to form the TFC, such as ALD, CVD, and the like. In an embodiment, the deep via opening 125 may pass through only buildup layers 101. However, as will be described in greater detail below, the deep via opening 125 may pass through traces 103, pads 104, and the like. In an embodiment, the deep via opening 125 may have tapered sidewalls. That is, a top of the deep via opening 125 may be wider than a bottom of the deep via opening 125.

In an embodiment, the TFC may comprise a first electrode 111, a dielectric layer 112, and a second electrode 113. The first electrode 111 may be a conformal layer that lines the sidewalls of the deep via opening 125. The first electrode 111 may have a thickness that is approximately 50 nm or less. As used herein, “approximately” refers to a range of values within ten percent of the stated value. For example, approximately 50 nm may refer to a range between 45 nm and 55 nm. The first electrode 111 may be an electrically conductive material.

Since the first electrode 111 lines the deep via opening 125 in a conformal manner, the cross-section of the first electrode 111 may be referred to as having a U-shaped cross-section. For example, the first electrode 111 may have a flat bottom portion over the first pad 105 and vertical portions along the sidewalls of the deep via opening 125. In some embodiments, a portion of the first electrode 111 may wrap outside of the deep via opening 125 over the topmost surface of the buildup layers 101.

The dielectric layer 112 may be conformally deposited over the first electrode 111. The dielectric layer 112 may have a thickness that is greater than a thickness of the first electrode 111. Though, the dielectric layer 112 may be approximately the same thickness as the first electrode 111 or thinner than the first electrode 111 in some embodiments. The dielectric layer 112 may be a high dielectric constant material. For example, the dielectric layer 112 may comprise titanium and oxygen (e.g., TiO₂), hafnium and oxygen (e.g., HfO₂), a polymer, or the like. The dielectric layer 112 may also have a U-shaped cross-section. The dielectric layer 112 may have a flat bottom surface and vertical portions along the sidewalls of the deep via opening 125. The top portion of the dielectric layer 112 may wrap outside of the deep via opening 125 as well.

In an embodiment, the second electrode 113 may be a plug that at least partially fills a remainder of the deep via opening 125. The second electrode 113 may be an electrically conductive material. The second electrode 113 may have a resistance that is lower than the resistance of the first electrode 111. That is, the second electrode 113 may be a material that is different than the first electrode 111. Further, while shown as a monolithic structure, the second electrode 113 may include a bi-layer architecture. For example, a conformal first portion may line the dielectric layer 112 and a second portion may fill the remainder of the deep via opening 125. In an embodiment, the second pad 107 may be provided over the second electrode 113.

Referring now to FIG. 1B, a zoomed in cross-sectional illustration of a portion 120 of the TFC in FIG. 1A is shown, in accordance with an embodiment. As shown, a deep via opening 125 is provided through the buildup layer 101. The deep via opening 125 has a sloped sidewall surface. The first electrode 111 is provided directly in contact with the sidewall surface of the deep via opening 125. Since the first electrode 111 is formed with a conformal deposition process, the first electrode 111 may have an outer surface that is also sloped. In an embodiment, the dielectric layer 112 is conformally deposited over the first electrode 111. As shown, the dielectric layer 112 may be thicker than the first electrode 111, though embodiments are not limited to such relationships. In an embodiment, the second electrode 113 is directly over the sloped outer surface of the dielectric layer 112. The second electrode 113 may be a bulk material that fills the remainder of the deep via opening 125. Though, in other embodiments, a bi-layer approach with a conformal first layer and a bulk filling second layer can also be used in some embodiments.

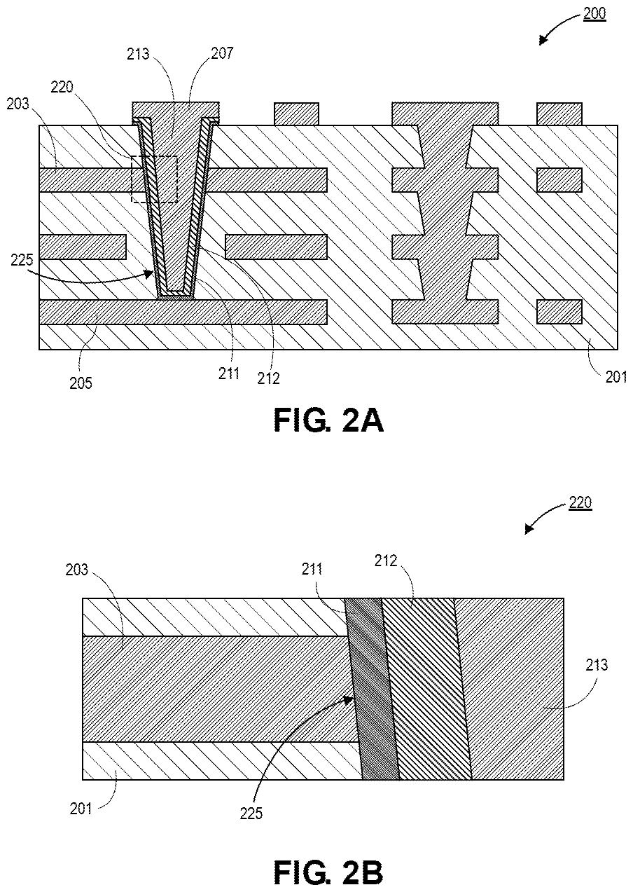

Referring now to FIG. 2A, a cross-sectional illustration of a portion of an electronic package 200 is shown, in accordance with an embodiment. In an embodiment, the electronic package 200 may comprise a plurality of buildup layers 201. Conductive routing may be provided in the buildup layers 201. For example, traces 203 may be provided in the buildup layers 201. In an embodiment, a first pad 205 and a second pad 207 may be provided on opposite sides of a TFC.

The TFC may be formed in a deep via opening 225. The deep via opening 225 may pass through one or more traces 203. In a particular embodiment, the deep via opening 225 passes through a top trace 203. Passing through the top trace 203 results in the trace 203 directly contacting the TFC. For example, the first electrode 211 of the TFC may directly contact the trace 203. The remainder of the TFC (i.e., the dielectric layer 212 and the second electrode 213) may fill the remainder of the deep via opening 225.

Referring now to FIG. 2B, a zoomed in cross-sectional illustration of the region 220 in FIG. 2A is shown, in accordance with an embodiment. As shown, a deep via opening 225 is provided through the buildup layer 201 and the trace 203. The deep via opening 225 has a sloped sidewall surface. The sloped sidewall surface may also pass through the trace 203. The first electrode 211 is provided directly in contact with the sidewall surface of the deep via opening 225 and the trace 203. Since the first electrode 211 is formed with a conformal deposition process, the first electrode 211 may have an outer surface that is also sloped. In an embodiment, the dielectric layer 212 is conformally deposited over the first electrode 211. As shown, the dielectric layer 212 may be thicker than the first electrode 211, though embodiments are not limited to such relationships. In an embodiment, the second electrode 213 is directly over the sloped outer surface of the dielectric layer 212. The second electrode 213 may be a bulk material that fills the remainder of the deep via opening 225. Though, in other embodiments, a bi-layer approach with a conformal first layer and a bulk filling second layer can also be used in some embodiments.

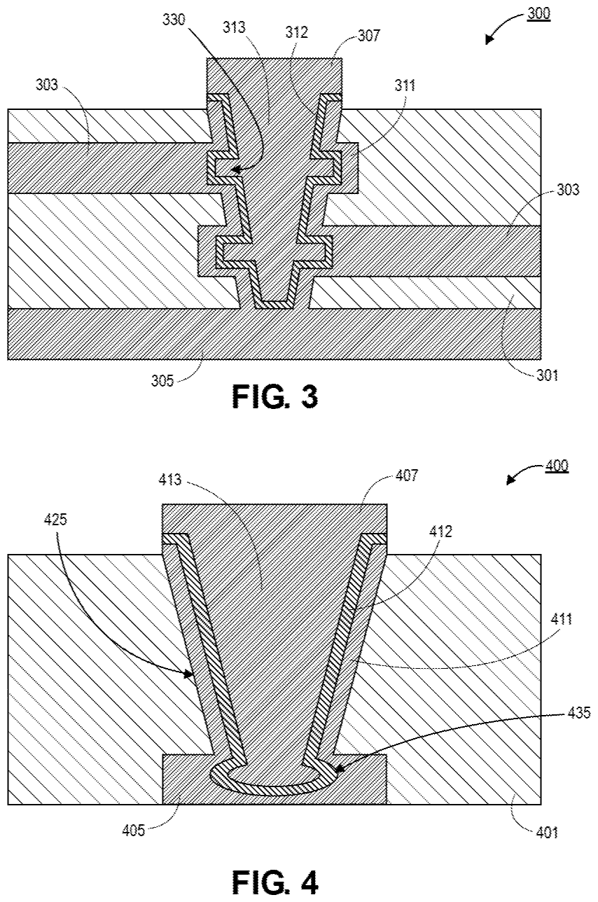

Referring now to FIG. 3, a cross-sectional illustration of a portion of an electronic package 300 is shown, in accordance with an embodiment. In an embodiment, the electronic package 300 may comprise buildup layers 301. The buildup layers 301 may be provided over a core (not shown), or the electronic package 300 may be coreless. In an embodiment, a first pad 305 may be at the bottom of the TFC and a second pad 307 may be at the top of the TFC. The TFC may also pass through one or more traces 303 or other conductive features.

In an embodiment, the TFC may comprise a first electrode 311, a dielectric layer 312, and a second electrode 313. The TFC may have a saw-tooth shaped profile. For example, protrusions 330 may be provided along the height of the TFC. The protrusions 330 increase the surface area of the TFC and increases capacitance density. In an embodiment, the protrusions 330 may be provided adjacent to the traces 303. Particularly, an etching process may be used to etch back the traces 303. The etched back cavity can then be conformally lined with the first electrode 311 and the dielectric layer 312. The second electrode 313 may then fill the remainder of the etched cavity. In the illustrated embodiment, a set of four protrusions 330 are shown for example. Though, any number of protrusions may be used, depending on how many buildup layers 301 the TFC passes through.

Referring now to FIG. 4, a cross-sectional illustration of a portion of an electronic package 400 is shown, in accordance with an embodiment. In an embodiment, the electronic package 400 may comprise buildup layers 401. The buildup layers 401 may be provided over a core (not shown), or the electronic package 400 may be coreless. In an embodiment, a first pad 405 may be at the bottom of the TFC and a second pad 407 may be at the top of the TFC.

The TFC may be provided within a deep via opening 425. For example, a first electrode 411 may line the deep via opening 425, and a dielectric layer 412 may be provided conformally over the first electrode 411. In an embodiment, a second electrode 413 may substantially fill the remainder of the deep via opening 425. In an embodiment, a cavity 435 is provided in the first pad 405. The cavity 435 may be formed with an isotropic etching process after formation of the deep via opening 425. The cavity 435 may be conformally lined with the dielectric layer 412 and filled with the second electrode 413.

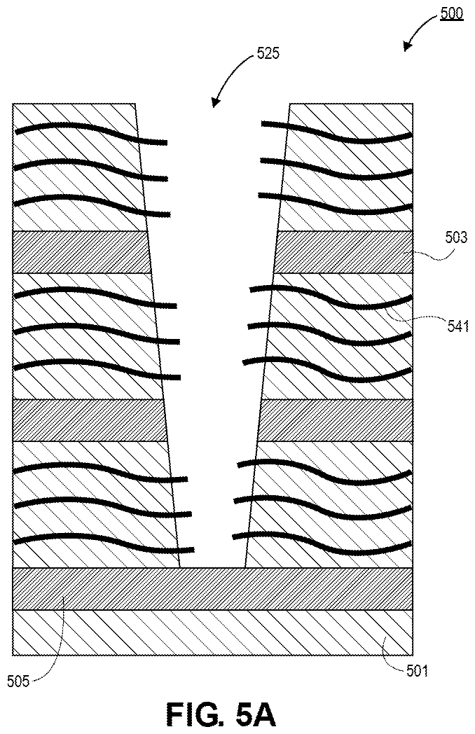

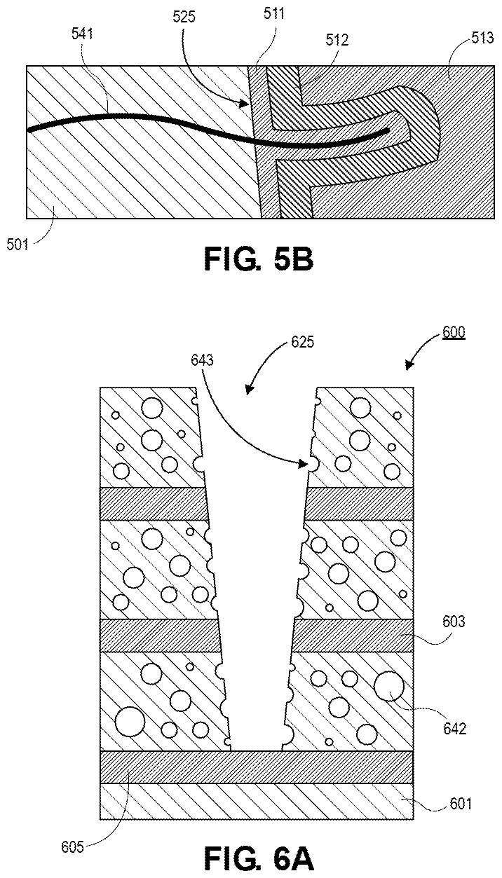

Referring now to FIG. 5A, a cross-sectional illustration of a portion of an electronic package 500 is shown, in accordance with an embodiment. In an embodiment, the electronic package 500 may comprise buildup layers 501. The buildup layers 501 may be provided over a core (not shown) or the electronic package 500 may be coreless. In an embodiment, a pad 505 is provided towards the bottom of the buildup layers 501. In an embodiment, the pad 505 may be at the bottom of a deep via opening 525. The deep via opening 525 may have tapered sidewalls so that a top of the deep via opening 525 is wider than a bottom of the deep via opening 525. The deep via opening 525 may pass through one or more traces 503.

In an embodiment, the buildup layers 501 may be reinforced with fibers 541, such as glass fibers or the like. During the formation of the deep via opening 525, the fibers 541 may be broken and their ends may remain protruding out the sidewalls of the deep via opening 525. The protruding portions of the fibers may be used in order to increase the capacitance density of the TFC.

Referring now to FIG. 5B, a zoomed in cross-sectional illustration of one of the fiber 541 after formation of the TFC is shown, in accordance with an embodiment. As shown, the first electrode 511 may conform to the sidewalls of the deep via opening 525 and wrap around the surface of the protruding fiber 541. Such an architecture may be enabled through the use of a conformal deposition process such as ALD, CVD, or the like. After the first electrode 511 is deposited, the dielectric layer 512 may be conformally deposited over the first electrode 511. The second electrode 513 may then be deposited over the dielectric layer 512 in order to at least partially fill the deep via opening 525.

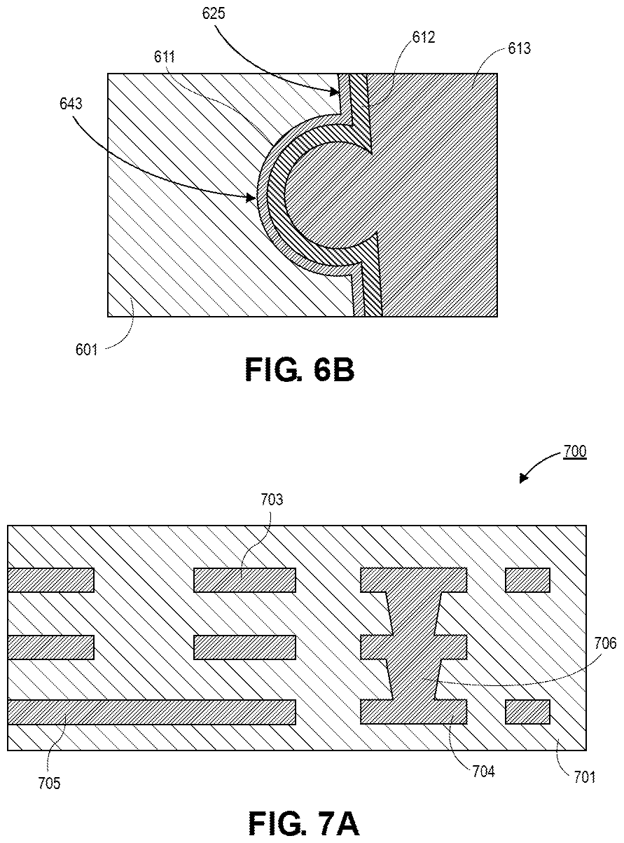

Referring now to FIG. 6A, a cross-sectional illustration of a portion of an electronic package 600 is shown, in accordance with an embodiment. In an embodiment, the electronic package 600 may comprise buildup layers 601. The buildup layers 601 may be provided over a core (not shown) or the electronic package 600 may be coreless. In an embodiment, a pad 605 is provided towards the bottom of the buildup layers 601. In an embodiment, the pad 605 may be at the bottom of a deep via opening 625. The deep via opening 625 may have tapered sidewalls so that a top of the deep via opening 625 is wider than a bottom of the deep via opening 625. The deep via opening 625 may pass through one or more traces 603.

In an embodiment, the buildup layers 601 may be reinforced with filler particles 642, such as glass filler particles 642. In an embodiment, the filler particles 642 at the surface of the deep via opening 625 may be etched in order to form cavities 643. The cavities 643 increase the surface area of the sidewalls of the deep via opening 625. As such, the subsequently formed TFC will have a higher capacitance density.

Referring now to FIG. 6B, a zoomed in cross-sectional illustration of a cavity 643 is shown, in accordance with an embodiment. As shown, the first electrode 611 is conformal to the sidewall of the deep via opening 625 and the cavity 643. The dielectric layer 612 may then be formed along the first electrode 611 in a conformal manner. The remainder of the cavity 643 and the deep via opening 625 may be at least partially filled by the second electrode 613.

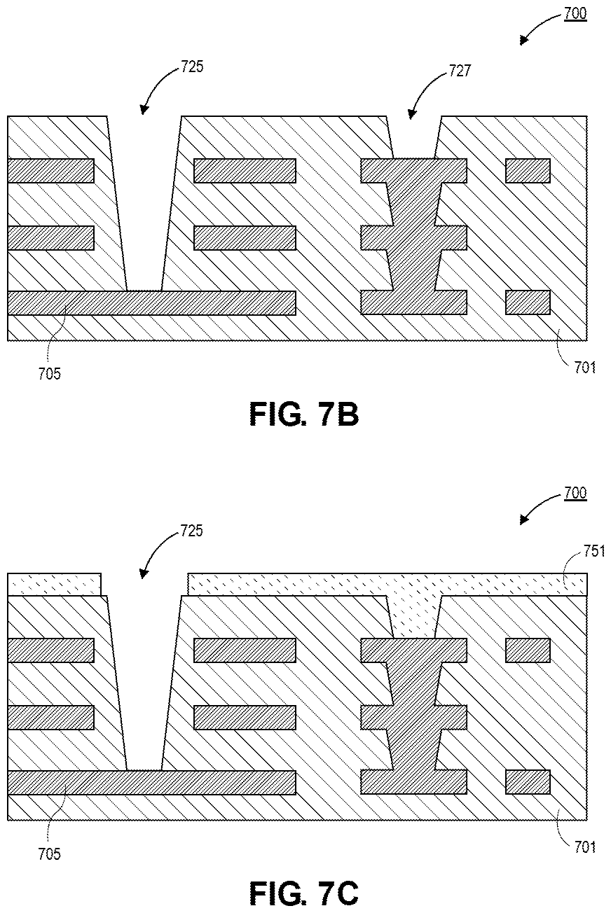

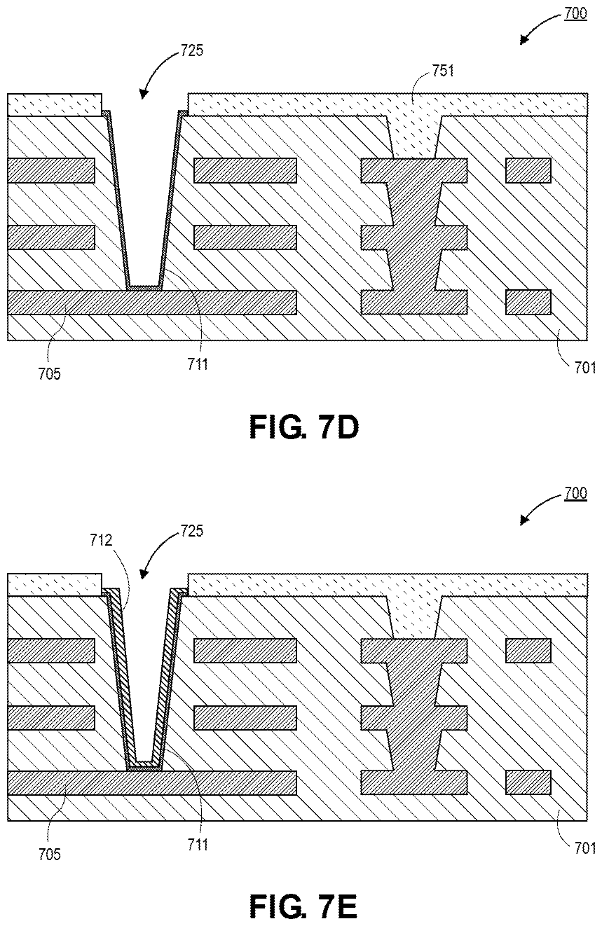

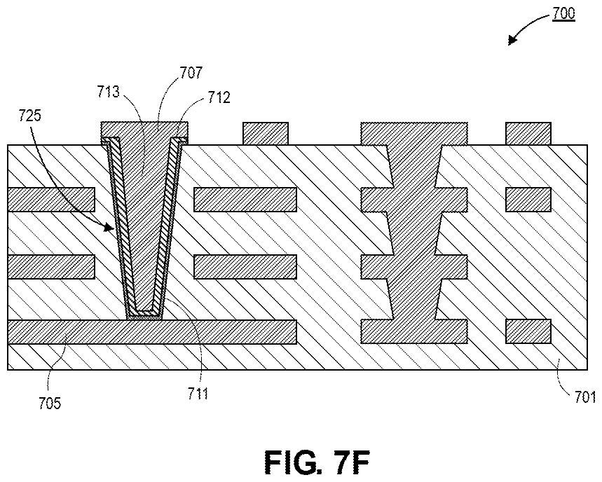

Referring now to FIGS. 7A-7F, a series of cross-sectional illustrations depicting a process for forming a TFC in a deep via opening is shown, in accordance with an embodiment. In the illustrated embodiment, the TFC is similar to the TFC shown in FIG. 1A. Though, it is to be appreciated that TFCs similar to any of the embodiments disclosed herein may be made using similar processing operations, as those skilled in the art will appreciated.

Referring now to FIG. 7A, a cross-sectional illustration of a portion of an electronic package 700 is shown, in accordance with an embodiment. In an embodiment, the electronic package 700 may comprise a plurality of buildup layers 701. The buildup layers 701 may be provided over a core (not shown), or the electronic package 700 may be coreless. While shown as a single monolithic structure, it is to be appreciated that a plurality of buildup layers 701 may be laminated over each other in some embodiments.

In an embodiment, the electronic package may comprise conductive routing embedded in the buildup layers 701. For example, pads 704, traces 703, and vias 706 may be formed in the buildup layers 701. A bottom pad 705 (or trace 705) may be provided proximate to a bottom of the buildup layers 701. The bottom pad 705 may be coupled to a ground voltage and may be part of the subsequently formed TFC.

Referring now to FIG. 7B, a cross-sectional illustration of the electronic package after via openings are formed is shown, in accordance with an embodiment. In an embodiment, a first via opening 727 may be formed over the pads and vias. A second deep via opening 725 may be provided over the bottom pad 705. The via openings 727 and 725 may be formed with any suitable subtractive process, such as etching, laser drilling, or the like.

In an embodiment, the deep via opening 725 may have an aspect ratio that is approximately 5:1 or greater, approximately 10:1 or greater, or approximately 20:1 or greater. In an embodiment, the deep via opening 725 may pass through two or more buildup layers 701. Additionally, in some embodiments, sidewalls of the deep via opening 725 may be sloped so that a top of the deep via opening 725 is wider than a bottom of the deep via opening 725. The deep via opening 725 may expose the bottom pad 705.

Referring now to FIG. 7C, a cross-sectional illustration of the electronic package after a resist layer 751 is deposited over the buildup layers 701 is shown, in accordance with an embodiment. The resist layer 751 may be any suitable resist formulation. In a particular embodiment, the resist layer 751 is a dry film resist (DFR). The resist layer 751 may fill the via opening 727. The portion of the resist layer 751 in the deep via opening 725 may be removed with a patterning process. In some embodiments, a width of the opening in the resist layer 751 may be wider than a maximum width of the deep via opening 725. That is, a topmost surface of the buildup layers 701 may be exposed adjacent to the deep via opening 725.

Referring now to FIG. 7D, a cross-sectional illustration of the electronic package 700 after a first electrode 711 is formed is shown, in accordance with an embodiment. In an embodiment, the first electrode 711 may be formed with a conformal deposition process, such as an ALD process, a CVD process, or the like. In an embodiment, the first electrode 711 may have a U-shaped cross-section with a flat bottom region and vertical sidewall portions along the sidewall of the deep via opening 725. The first electrode 711 may have a thickness that is approximately 50 nm or less.

Referring now to FIG. 7E, a cross-sectional illustration of the electronic package 700 after a dielectric layer 712 is formed is shown, in accordance with an embodiment. In an embodiment, the dielectric layer 712 may be a high-k dielectric material. For example, the dielectric layer 712 may comprise titanium and oxygen (e.g., TiO₂), hafnium and oxygen (e.g., HfO₂), a polymer, or the like. The dielectric layer 712 may also be deposited with a conformal deposition process, such as an ALD process, a CVD process, or the like. In an embodiment, the dielectric layer 712 may be thicker than the first electrode 711 in some embodiments. The dielectric layer 712 may also have a U-shaped cross-section.

Referring now to FIG. 7F, a cross-sectional illustration of the electronic package after the second electrode 713 and the second pad 707 are formed is shown, in accordance with an embodiment. In an embodiment, the second electrode 713 may substantially fill the remainder of the deep via opening 725. While shown as a single layer, a bi-layer approach may also be used for the second electrode 713. In that situation, a first conformal portion may be provided over the dielectric layer 712, and a second fill portion may fill the remainder of the deep via opening 725. In an embodiment, the second pad 707 may be coupled to a power voltage, Vcc, or the like.

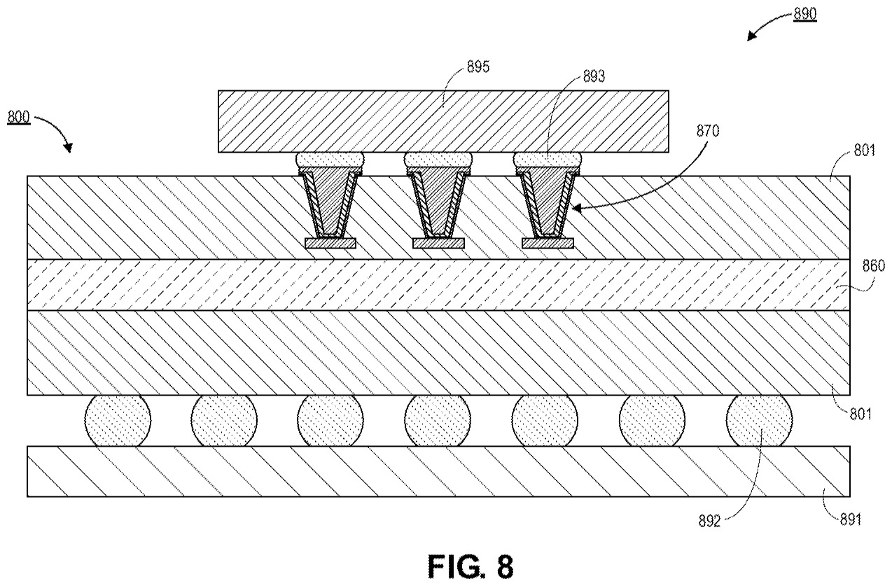

Referring now to FIG. 8, a cross-sectional illustration of a computing system 890 is shown, in accordance with an embodiment. In an embodiment, the computing system 890 may comprise a board 891, such as a printed circuit board (PCB). The board 891 may be coupled to an electronic package 800 through interconnects 892, such as solder balls, sockets, or the like.

In an embodiment, the electronic package 800 may comprise a core 860. The core 860 may be a glass core 860, an organic core 860, or the like. In an embodiment, buildup layers 801 may be provided above and below the core 860. In a particular embodiment, one or more TFCs 870 are provided in the buildup layers 801 above the core 860. The TFCs 870 may be formed in deep via openings that pass through two or more buildup layers 801. The TFCs 870 may comprise a first electrode, a dielectric layer, and a second electrode. At least the first electrode and the dielectric layer may be conformal to the deep via opening. At least part of the second electrode may fill the remainder of the deep via opening.

In an embodiment, the TFCs 870 may be coupled to a die 895 through interconnects 893. The interconnects 893 may be any suitable first level interconnect (FLI) architecture. The die 895 may be one die of multiple dies in some embodiments. The die 895 may be any type of compute die, such as a central processing unit (CPU), a graphics processing unit (GPU), an XPU, a system on a chip (SoC), an application specific integrated circuit (ASIC), a communications die, or the like. One or more memory dies may also be included in the computing system 890.

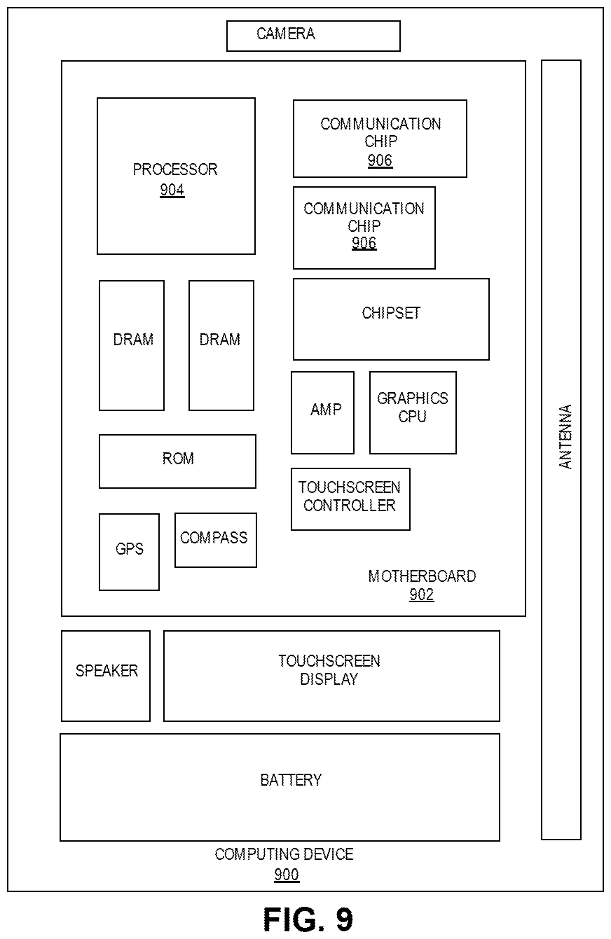

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package that comprises buildup layers with a deep via opening that is at least partially filled with a TFC that includes a first electrode, a dielectric layer, and a second electrode, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package that comprises buildup layers with a deep via opening that is at least partially filled with a TFC that includes a first electrode, a dielectric layer, and a second electrode, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate, wherein the package substrate comprises a plurality of stacked dielectric layers; an opening into the package substrate, wherein the opening passes through at least two of the plurality of dielectric layers; a first pad at the bottom of the opening; a capacitor disposed in the opening; and a second pad over the capacitor.

Example 2: the electronic package of Example 1, wherein the capacitor comprises: a first electrode that lines the opening; a capacitor dielectric that lines the first electrode; and a second electrode that at least partially fills a remainder of the opening.

Example 3: the electronic package of Example 2, wherein a thickness of the first electrode is thinner than a thickness of the capacitor dielectric.

Example 4: the electronic package of Example 2 or Example 3, wherein a resistivity of the first electrode is higher than a resistivity of the second electrode.

Example 5: the electronic package of Examples 1-4, wherein the opening passes through a trace in one of the dielectric layers, wherein the trace directly contacts an electrode of the capacitor.

Example 6: the electronic package of Examples 1-5, wherein the capacitor has a saw tooth profile.

Example 7: the electronic package of Examples 1-6, wherein the capacitor extends into a cavity formed in the first pad.

Example 8: the electronic package of Examples 1-7, wherein the opening has tapered sidewalls with a top end that is wider than a bottom end.

Example 9: the electronic package of Examples 1-8, wherein a fiber passes through a wall of the opening, and wherein the capacitor lines the exposed portions of the fiber.

Example 10: the electronic package of Examples 1-9, wherein a cavity is provided along a sidewall of the opening, and wherein the capacitor lines the cavity.

Example 11: the electronic package of Examples 1-10, wherein the electronic package is part of a computing system for a personal computer, a server, a mobile device, a tablet, or an automobile.

Example 12: an electronic package, comprising: a core; buildup layers over the core; a first pad in one of the buildup layers; a thin film capacitor (TFC) that passes through two or more of the buildup layers; and a second pad over the TFC.

Example 13: the electronic package of Example 12, wherein the TFC comprises: a first electrode; a capacitor dielectric on the first electrode, wherein a k-value of the capacitor dielectric is equal to or greater than a k-value of a layer comprising silicon and oxygen; and a second electrode contacting the capacitor dielectric.

Example 14: the electronic package of Example 13, wherein the first electrode has a first U-shaped cross-section, wherein the capacitor dielectric has a second U-shaped cross-section, and wherein the second electrode is a plug that fills the second U-shaped cross-section.

Example 15: the electronic package of Examples 12-14, wherein the first electrode has a resistance that is higher than a resistance of the second electrode.

Example 16: the electronic package of Examples 12-15, wherein the TFC has tapered sidewalls.

Example 17: the electronic package of Examples 12-16, wherein TFC directly contacts a trace between the first pad and the second pad.

Example 18: the electronic package of Examples 12-17, wherein the first pad is coupled to a ground voltage, and wherein the second pad is coupled to a Vcc voltage.

Example 19: a computing system, comprising: a board; an electronic package coupled to the board, wherein the electronic package comprises: a core; buildup layers over and under the core; a capacitor in two or more buildup layers over the core; and a die coupled to the electronic package.

Example 20: the computing system of Example 19, wherein the computing system is part of a personal computer, a server, a mobile device, a tablet, or an automobile.

What is claimed is:

1. An electronic package, comprising:
a package substrate, wherein the package substrate comprises a plurality of stacked dielectric layers;
an opening into the package substrate, wherein the opening passes through at least two of the plurality of dielectric layers;
a first pad at the bottom of the opening;
a capacitor disposed in the opening; and
a second pad over the capacitor.

2. The electronic package of claim 1, wherein the capacitor comprises:
a first electrode that lines the opening;
a capacitor dielectric that lines the first electrode; and
a second electrode that at least partially fills a remainder of the opening.

3. The electronic package of claim 2, wherein a thickness of the first electrode is thinner than a thickness of the capacitor dielectric.

4. The electronic package of claim 2, wherein a resistivity of the first electrode is higher than a resistivity of the second electrode.

5. The electronic package of claim 1, wherein the opening passes through a trace in one of the dielectric layers, wherein the trace directly contacts an electrode of the capacitor.

6. The electronic package of claim 1, wherein the capacitor has a saw tooth profile.

7. The electronic package of claim 1, wherein the capacitor extends into a cavity formed in the first pad.

8. The electronic package of claim 1, wherein the opening has tapered sidewalls with a top end that is wider than a bottom end.

9. The electronic package of claim 1, wherein a fiber passes through a wall of the opening, and wherein the capacitor lines the exposed portions of the fiber.

10. The electronic package of claim 1, wherein a cavity is provided along a sidewall of the opening, and wherein the capacitor lines the cavity.

11. The electronic package of claim 1, wherein the electronic package is part of a computing system for a personal computer, a server, a mobile device, a tablet, or an automobile.

12. An electronic package, comprising:
a core;
buildup layers over the core;
a first pad in one of the buildup layers;
a thin film capacitor (TFC) that passes through two or more of the buildup layers; and
a second pad over the TFC.

13. The electronic package of claim 12, wherein the TFC comprises:
a first electrode;
a capacitor dielectric on the first electrode, wherein a k-value of the capacitor dielectric is equal to or greater than a k-value of a layer comprising silicon and oxygen; and
a second electrode contacting the capacitor dielectric.

14. The electronic package of claim 13, wherein the first electrode has a first U-shaped cross-section, wherein the capacitor dielectric has a second U-shaped cross-section, and wherein the second electrode is a plug that fills the second U-shaped cross-section.

15. The electronic package of claim 13, wherein the first electrode has a resistance that is higher than a resistance of the second electrode.

16. The electronic package of claim 12, wherein the TFC has tapered sidewalls.

17. The electronic package of claim 12, wherein TFC directly contacts a trace between the first pad and the second pad.

18. The electronic package of claim 12, wherein the first pad is coupled to a ground voltage, and wherein the second pad is coupled to a Vcc voltage.

19. A computing system, comprising:
a board;
an electronic package coupled to the board, wherein the electronic package comprises:
a core;
buildup layers over and under the core;
a capacitor in two or more buildup layers over the core; and
a die coupled to the electronic package.

20. The computing system of claim 19, wherein the computing system is part of a personal computer, a server, a mobile device, a tablet, or an automobile.
